(19) United States
(12) Patent Application Publication
(10) Pub. No.: US 2004/0232109 A1
(43) Pub. Date: Nov. 25, 2004

(54) Mask unit and film deposition apparatus using the same

(76) Inventor: Mitsuhiro Yoshinaga, Katano-shi (JP)

Correspondence Address: RATNERPRESTIA, P O BOX 980, VALLEY FORGE, PA, 19482-0980, US

(21) Appl. No.: 10/849,949

(22) Filed: May 19, 2004

(30) Foreign Application Priority Data
May 21, 2003 (JP) 2003-143032

(51) Int. Cl. C23C 16/00; C23F 1/00

(52) U.S. Cl. 216/54; 427/248.1; 427/256; 216/41

(57) ABSTRACT

A mask unit is formed by providing a pattern forming mask disposed in close contact with the top face of a substrate held on a substrate holder and having prescribed pattern openings, and a shielding mask having pattern openings larger by prescribed dimension than the pattern openings in this pattern forming mask. The pattern forming mask and the shielding mask are held on the substrate. A prescribed clearance is provided between the pattern forming mask and the shielding mask.

### FIELD OF THE INVENTION

The present invention concerns a mask unit and a film deposition apparatus using it for forming prescribed patterns of conductive film, insulating film, etc. on a substrate by vacuum deposition method using the mask unit.

### BACKGROUND OF THE INVENTION

Explanation will be given on a film deposition apparatus using a conventional mask unit, about an example of sputtering method, with reference to FIG. 7 to FIG. 9.

FIG. 7 is a schematic diagram for explaining the construction of a sputtering apparatus which is an example of conventional film deposition apparatus, and FIG. 8 is a sectional view indicating the construction of a mask unit used for it. The dimension in the direction of thickness of the sectional view is expanded, to make the construction of the mask unit easier to understand.

As shown in FIG. 7, a conventional film deposition apparatus by sputtering method is constructed by comprising a sputtering target 2 (hereinafter referred to as “target 2”) which is a source of vapor deposition and a mask unit 3 stored in a vacuum chamber 1. There is Japanese Patent Unexamined Publication No. S55-11185, etc., for example.

To the vacuum chamber 1 is connected, through a valve 5, a vacuum pump 4 for performing evacuation. Moreover, the target 2 is connected to the target electrode 6 disposed in the vacuum chamber 1 by means of a non-illustrated support. Furthermore, the mask unit 3 is mounted on a table 8 connected to the substrate supporting stand 7 facing the target 2.

And, as shown in FIG. 8, a substrate 10 is placed at the center of a substrate holder 9, and on the top face of this substrate 10 is placed a mask 11 for forming patterns (hereinafter referred to as “mask”) made of a magnetic metal sheet with a thickness of 0.1 mm to 0.2 mm having various kinds of pattern openings 12 corresponding to the patterns desired to be formed. Further on its top face is disposed a shielding mask 13 made of a metal sheet with a thickness of approximately 0.5 mm in a way to be in close contact with the mask 11. In this shielding mask 13 are provided pattern openings 14 identical to or slightly larger than the pattern openings 12 in the mask 11.

And, those members are fixed to the substrate holder 9 by means of fastening screws 16 through a frame 15. Still more, the mask 11 is attracted by magnets 17 mounted on the substrate holder 9, to be put in close contact with the substrate 10. The table 8 on which is mounted the substrate holder 9 is maintained at prescribed temperature by the method of water cooling, etc.

In a film deposition apparatus constructed as described above, the target electrode 6 generates a plasma discharge when it is applied voltage. And, the ions produced with the plasma discharge collided with the target 2. As a result of this collision of ions, the vapor deposition material which rushed out of the target 2 passes through the pattern openings 14 of the shielding mask 13 and the pattern openings 12 of the mask 11, and deposits the surface of the substrate 10. Consequently, prescribed patterns same as the pattern openings 12 of the mask 11 are formed on the surface of the substrate 10. The act of forming patterns on the substrate 10 by using a mask unit 3 constructed as above is practiced in the same way also in vacuum deposition method.

And, the purpose of disposing a shielding mask 13 on the mask unit 3 is to prevent the mask 11 from being deformed, under the stress produced with the vapor deposition material which rushed out of the target 2 during the film deposition process. At the same time, it also aims at preventing dimensional changes due to thermal expansion of the mask 11 and the substrate 10, caused by radiant heat from the source of vapor deposition which is the target 2 during the film deposition and heat by the collision of ions at the time of plasma discharge. The influences of such dimensional changes become conspicuous, especially in the outer circumferential area of the substrate 10. For that reason, there are cases where it becomes impossible to obtain dimensions and shape same as those of the pattern openings 12 in the initial period, in the outer circumferential area of the substrate 10.

Explanation will further be given, with reference to FIG. 9, on the influence of such dimensional changes due to thermal expansion of the mask 11 and the substrate 10 produced during the film deposition process.

FIG. 9 is a plan view showing an example of displacement of patterns on the surface of the substrate 10 at the time of film deposition performed with the above-described construction of the mask unit 3. Since the mask 11 and the substrate 10 result a thermal expansion with heating, the patterns formed on the substrate 10 are displaced in the outer circumferential direction indicated with arrow mark, from the initial position of the pattern 10A to the position indicated with dotted line. This displacement results from the difference in coefficient of thermal expansion between the mask 11 and the substrate 10. In FIG. 9, an example is shown in which the coefficient of thermal expansion of the mask 11 is larger than that of the substrate 10. As a result, the shape of patterns formed on the substrate 10 has a wider extent compared with the shape of patterns to be normally produced as indicated with hatching in FIG. 9. This phenomenon is produced conspicuously in the case where a resin substrate with generally a large coefficient of thermal expansion is used as substrate 10.

Namely, on a conventional mask unit 3, the shielding mask 13 and the mask 11 are manufactured with a metal sheet as thin as possible, so that the pattern shape formed on the substrate 10 may not be influenced by the incident angle of the vapor deposition material. At the same time, the two members are disposed in away to overlap with each other, and this facilitates transmission of heat from the shielding mask 13 to the mask 11. For that reason, the heat from the shielding mask 13 is transmitted to the mask 11 by thermal conduction, and the mask 11 and the substrate 10 produce dimensional changes with thermal expansion. This results in displacement of patterns due to dimensional changes. For example, when forming a copper (Cu) film of 2.0 μm, a nickel (Ni) film of 0.75 μm and a gold (Au) film of 0.1 μm one upon another on a substrate made of resin such as polyimide resin with a size of 100 mm×100 mm, a displacement of patterns of approximately 100 μm is produced in the outer circumferential area of the substrate 10, if you either increase the input power applied to the target 2 to raise the film deposition speed or extend the film deposition time.

Yet more, a phenomenon is produced in which the mask 11 partially deforms under the influence of heat, making it impossible to form patterns with sharp edge.

### SUMMARY OF THE INVENTION

The mask unit according to the present invention comprises a pattern forming mask disposed closely above a film, which is formed on a surface of a substrate held on a substrate holder, and having a prescribed pattern opening, and a shielding mask disposed above the pattern forming mask and having a pattern opening larger than the pattern opening of the pattern forming mask, wherein the pattern forming mask and the shielding mask are held with a prescribed clearance therebetween above the substrate.

The film deposition apparatus according to the present invention includes the following construction

(a) a mask unit including:

(a-1) a pattern forming mask disposed closely above a film, which is formed on a surface of a substrate held on a substrate holder, and having a prescribed pattern opening;

(a-2) a shielding mask disposed above the pattern forming mask and having a pattern opening larger than the pattern opening of the pattern forming mask;

(b) a table cooled at a prescribed temperature and placed so as to be contacted with a lower surface of the substrate holder of the mask unit; and

(c) a vapor deposition source, which is placed at a vacuum chamber, for forming a prescribed film on a surface of the substrate disposed on the mask unit,

wherein the pattern forming mask and the shielding mask are held with a prescribed clearance therebetween above the substrate.

Moreover, a method of manufacturing a sheet-like electronic component having at least 2 laminated films according to the present invention includes the following steps of:

(a) forming a first pattern on a surface of a sheet-like substrate by using a mask unit, the mask unit including:

a first pattern forming mask disposed closely above a film, which is formed on a surface of the sheet-like substrate held on a substrate holder, and having a prescribed pattern opening; and

a shielding mask disposed above the first pattern forming mask and having a pattern opening larger than the pattern opening of the first pattern forming mask, the first pattern forming mask and the shielding mask being held with a prescribed clearance therebetween above the substrate; and

(b) forming a second pattern on the first pattern by installing a second pattern forming mask, which differs from the first pattern forming mask, at the mask unit.

### BRIEF DESCRIPTION OF THE DRAWINGS

FIG. 1 is a sectional view showing the construction of a mask unit according to the first exemplary embodiment of the present invention.

FIG. 2 is a plan view of the shielding mask in a mask unit according to the first exemplary embodiment of the present invention, as seen from the pattern forming mask side.

FIG. 3 is a schematic diagram for explaining the construction of the film deposition apparatus according to the first exemplary embodiment of the present invention.

FIG. 4A is a plan view of the pattern forming mask in a mask unit according to the first exemplary embodiment of the present invention.

FIG. 4B is a plan view of the shielding mask in a mask unit according to the first exemplary embodiment of the present invention.

FIG. 5A is a plan view of an electronic component made by using the mask unit according to the first exemplary embodiment of the present invention.

FIG. 5B is a sectional view of an electronic component made by using a mask unit according to the first exemplary embodiment of the present invention.

FIG. 5C is a drawing explaining the relation of film position among a plurality of electronic components formed on a sheet -like substrate by using a mask unit according to the first exemplary embodiment of the present invention.

FIG. 6 is a sectional view showing the construction of a mask unit according to the second exemplary embodiment of the present invention.

FIG. 7 is a schematic diagram for explaining the construction of a mask unit used for a conventional film deposition apparatus.

FIG. 8 is a sectional view showing the construction of a mask unit used for a conventional film deposition apparatus.

FIG. 9 is a drawing showing an example of displacement of patterns produced at the time of formation of film made with a mask unit construction used for a conventional film deposition apparatus.

### DETAILED DESCRIPTION OF THE EXEMPLARY EMBODIMENTS

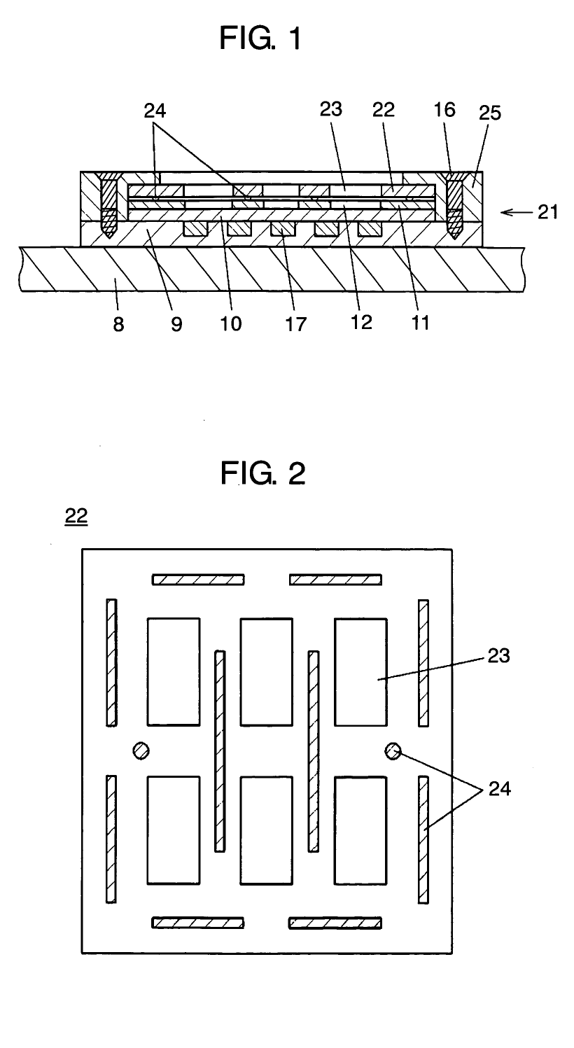

The first exemplary embodiment of the present invention will be explained hereinafter, with reference to FIG. 1 to FIG. 4.

Same symbols are used for elements identical to those explained in the section of prior art. In addition, the dimension in the direction of thickness of the sectional view is expanded, to make the construction of the mask unit easier to understand, in the same way as in the case of the prior art.

### First Exemplary Embodiment

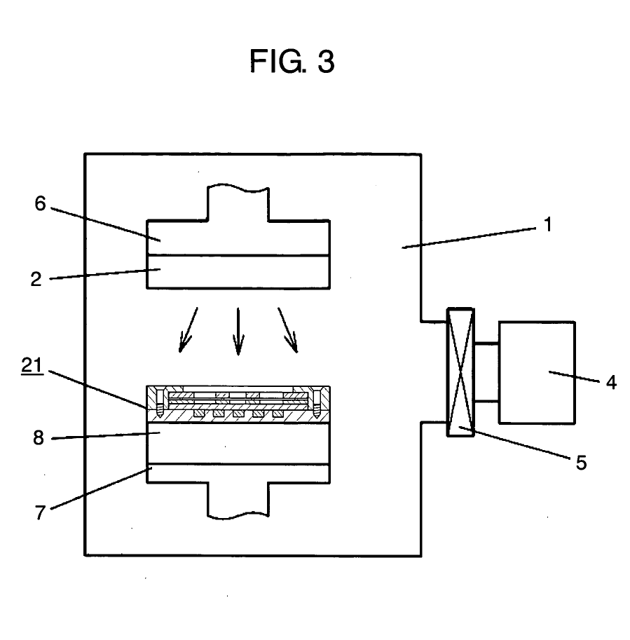

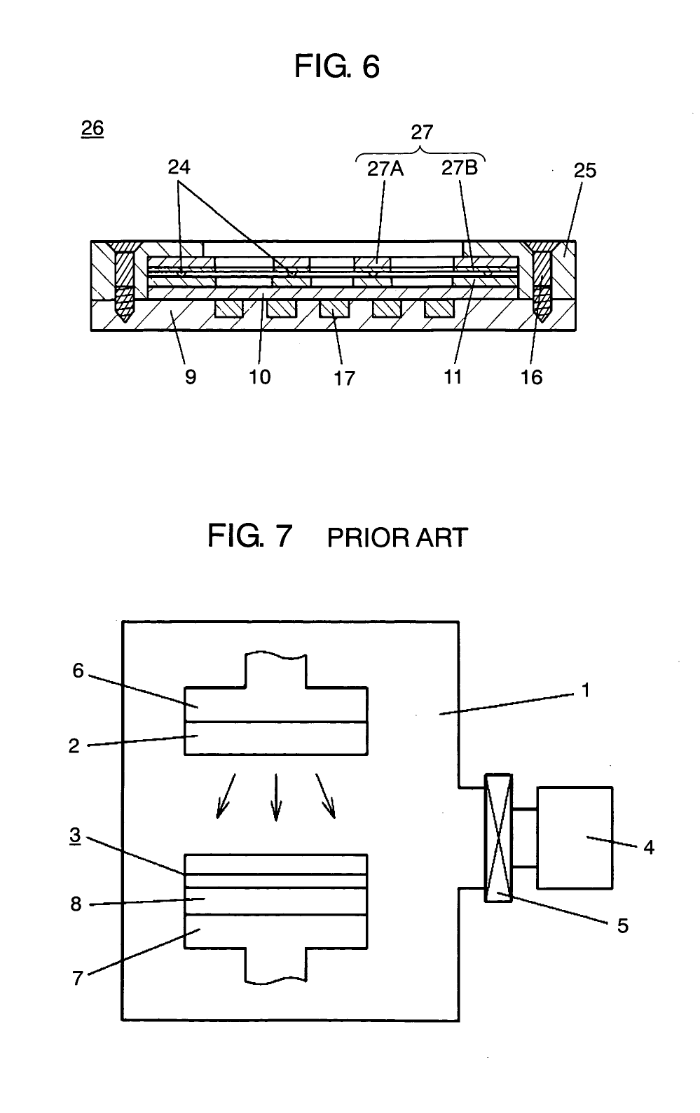

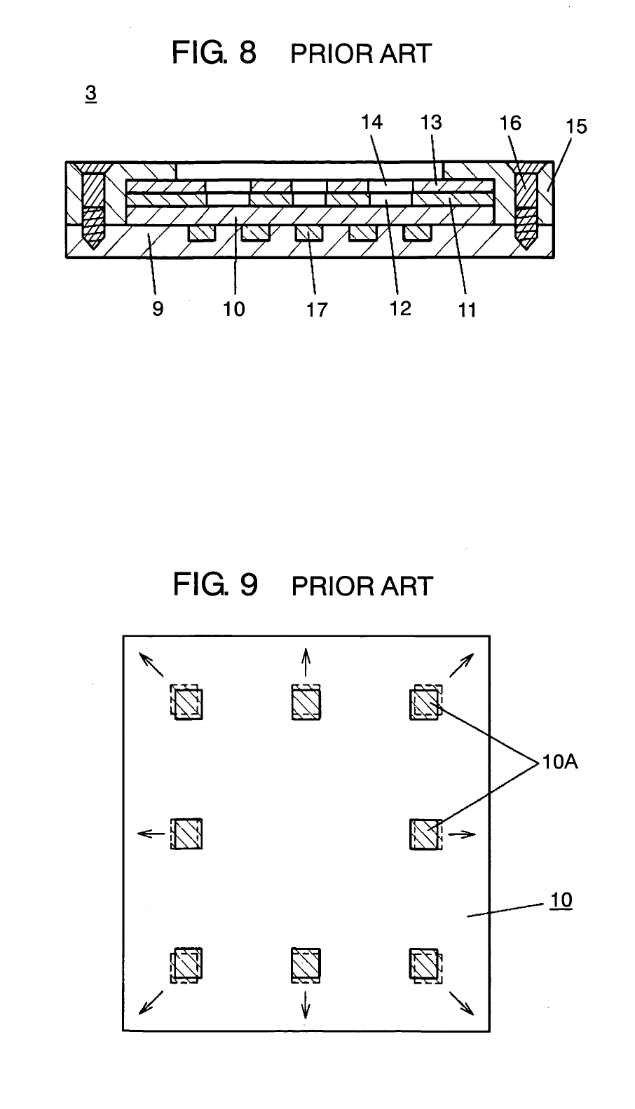

Explanation will be given hereinafter, on the mask unit according to the first exemplary embodiment of the present invention. Explanation on the basic construction of the film deposition apparatus according to this exemplary embodiment is omitted, because it is the same as that of the conventional film deposition apparatus indicated in FIG. 6, except for a difference in the construction of mask units as shown in FIG. 3.

FIG. 1 is a sectional view showing the construction of a mask unit according to this exemplary embodiment. The mask unit 21 is mounted in such away that the under surface of the substrate holder 9 gets in close contact with the table 8 of the film deposition apparatus. To ensure better contact, there are cases where the substrate holder 9 is mounted on the table 8 through a graphite sheet, for example. The table 8 is maintained at prescribed temperature or 20° C. for example, by the method of water cooling, etc. usually. For the substrate holder 9, it is desirable to use a material with comparatively good thermal conductivity and easy to machine, such as copper (Cu), aluminium (Al), stainless steel (SUS), iron (Fe) or alloys thereof, etc.

And, at the center on the top face of the substrate holder 9 is held the substrate 10 made of polyimide, etc. with a size of 100 mm square, for example. Moreover, the top face of this substrate 10 is covered with a pattern forming mask 11 of metal sheet with a thickness of 0.1 mm to 0.2 mm and a size of 100 mm square (hereinafter referred to as “mask”) in which are provided various kinds of pattern openings 12 in correspondence to the patterns desired to be formed. This mask 11, which shall preferably be attracted by magnets 17 loaded on the substrate holder 9 to be in close contact with the substrate 10, is made of an invar alloy, etc. for example. Furthermore, a shielding mask 22 having pattern openings 23 larger by prescribed dimension than the pattern openings 12 of the mask 11 and having a thickness of 0.5 mm or so and a size of 100 mm square is disposed in a way to be lapped on the top face of the mask 11. For this shielding mask 22, it is desirable to use a metallic material with excellent thermal conductivity, such as stainless steel (SUS),copper (Cu), or iron (Fe), etc. For this shielding mask 22, it may also be all right to use a material attracted by magnets 17 or non-magnetic material.

In a mask unit 21 having such construction, spacers 24 are provided between the mask 11 and the shielding mask 22, to secure a clearance of 0.1 mm to 0.5 mm, at the portion concerned.

These spacers 24 are realized, as shown in FIG. 2, by pasting heat-resistant tape of polyimide, etc. with a width of approximately 1 mm in linear or dotted shape between and around a plurality of pattern openings 23 provided in the shielding mask 22. FIG. 2 is a plan view of the shielding mask 22 as seen from the mask 11 side, with a construction in which the pattern openings 23 are provided in correspondence to the pattern openings 12 of the mask 11, and the spacers 24 are bonded around them.

And, the shielding mask 22, the mask 11, and the substrate 10 provided with those spacers 24 are fixed to the substrate holder 9 by means of fastening screws 16 through a frame 25.

By using a film deposition apparatus as shown in FIG. 3 on which is installed a mask unit 21 constructed as above, a film was formed, on the substrate 10, in a layered construction having a copper (Cu) film of 2.0 μm, a nickel (Ni) film of 0.75 μm and a gold (Au) film of 0.1 μm. As a result, the displacement of patterns due to thermal expansion of the mask 11 was found to be no more than 40 μm even at the pattern openings 23 disposed in the outer circumferential area of the substrate 10. This amount of displacement of patterns is no more than one half compared with that of the patterns formed with a conventional mask unit 3, and there was hardly any blurring of the pattern edge. The reason for it is that the shielding mask 22 of the mask unit 21 is disposed with a clearance of approximately 100 μm over the mask 11. Namely, even if the shielding mask 22 is heated with radiant heat from the target 2 in the film deposition process, etc., this heat is insulated in the direction from shielding mask 22 to mask 11 with a clearance, thus enabling to reduce temperature rise on the mask 11 and the substrate 10.

The above explanation was given with a construction in which the spacers 24 are disposed as shown in FIG. 2 in the portion of clearance between the mask 11 and the shielding mask 22, but the present invention is not restricted to such construction. For example, in the case where the surface area forming the pattern openings 23 provided in the shielding mask 22 is small and the rigidity of the shielding mask 22 is large, one may simply provide spacers 24 having prescribed clearance at the outer circumference of the pattern forming mask 11 and the shielding mask 22. Moreover, one may also use a shielding mask 22 at the outer circumference of which are formed convexities having prescribed clearance.

Furthermore, while a heat resistant resin tape such as polyimide, etc. is pasted in this exemplary embodiment, the present invention is not restricted to it. For example, the spacers 24 may be formed by coating a resin of low thermal conductivity or bonding ceramic balls, etc. at prescribed points, and there is no particular restriction to the material if only the material is of low thermal conductivity, can be formed at a thickness no smaller than approximately 100 μm and can be used in vacuum.

Still more, when disposing spacers 24 between the mask 11 and the shielding mask 22, one may integrate the construction of the mask 11 and the shielding mask 22 by bonding them in advance at least at the central part with the spacers 24 between them. This construction enables to handle the mask 11 and the shielding mask 22 in integrated way, thus facilitating their connection to and detachment from the mask unit 21. Yet more, the mask 11 is less subject to the influence of radiant heat, etc., by the shielding mask 22. In addition, for example, in the case where an invar alloy is used for the shielding mask 22, the shielding mask 22 integrated with the mask 11 is attracted by the magnets 17 in the state where prescribed clearance is secured. For that reason, there is no more particular need of providing the frame 25, enabling to simplify the construction of the mask unit 21.

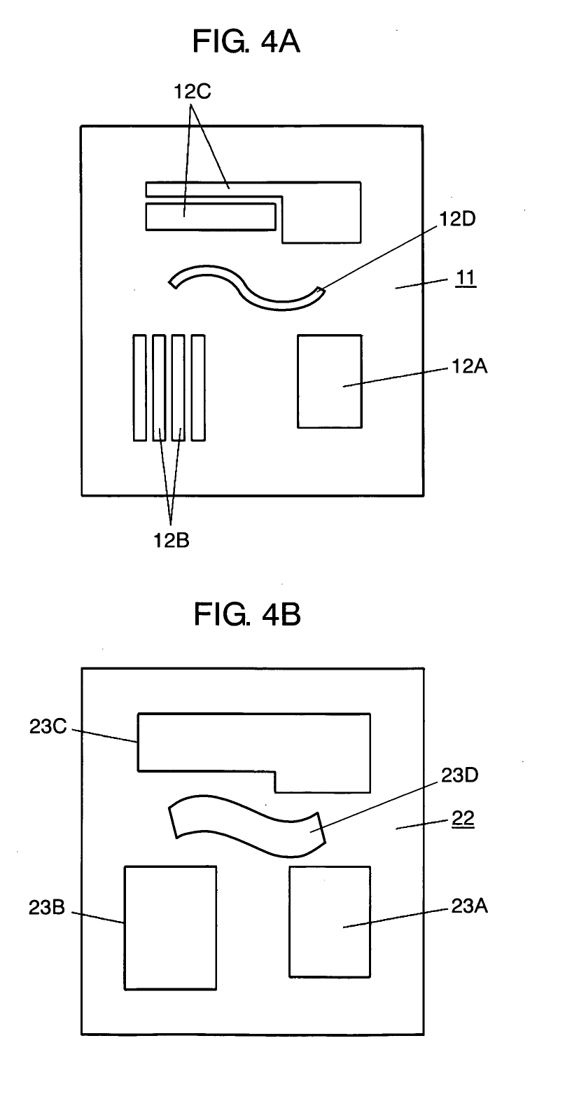

And, about the relationship between the pattern openings 12 of the mask 11 and the pattern openings 23 provided in the shielding mask 22, the construction indicated in FIG. 4 is desirable. FIG. 4A is a plan view of the pattern forming mask 11, while FIG. 4B is a plan view of the shielding mask 22. Namely, with reference to the comparatively large pattern opening 12A of the mask 11, the pattern opening 23A in the shielding mask 22 will have the same shape as that of the pattern opening 12A but larger by prescribed dimension or 0.5 mm for example. Moreover, with reference to the comparatively small pattern opening 12B of the mask 11, the pattern opening 23B in the shielding mask 22 will be realized in a shape combining a plurality of pattern openings 12B, and in a shape larger by 0.5 mm for example. Furthermore, in the case where the area between the pattern openings 12 is like the adjoining pattern opening 12C, in the mask 11, the pattern opening 23C will have a shape combining them. Still more, also against the pattern opening 12D in curved shape in the mask 11, the pattern opening 23D in the shielding mask 22 will have the same shape as that of the pattern opening 12D but larger by prescribed dimension or 0.5 mm for example in the same way as above.

By adopting those shapes for the pattern openings 23, it becomes possible to improve the shielding efficiency against heat of the shielding mask 22, and reduce shielding by the shielding mask 22 of the vapor deposition material passing through the pattern openings 12 of the mask 11 during the film deposition process.

As described above, according to this exemplary embodiment, the mask unit 21, provided above the mask 11 disposed on the substrate 10 in close contact with it and constructed by holding the shielding mask 22 having pattern openings 23 larger by prescribed dimension than the mask 11 with prescribed clearance against the latter, protects the mask 11 against heating by the radiant heat from the source of vapor deposition during the film deposition process and heat by collision of ions at the time of plasma discharge, etc. For that reason, production of blurring due to drop of positional accuracy of patterns or deformation of the mask 11, etc. resulting from thermal expansion of the mask 11 is controlled. And, also in a film deposition method using the mask 11, fine patterns can be produced with good accuracy.

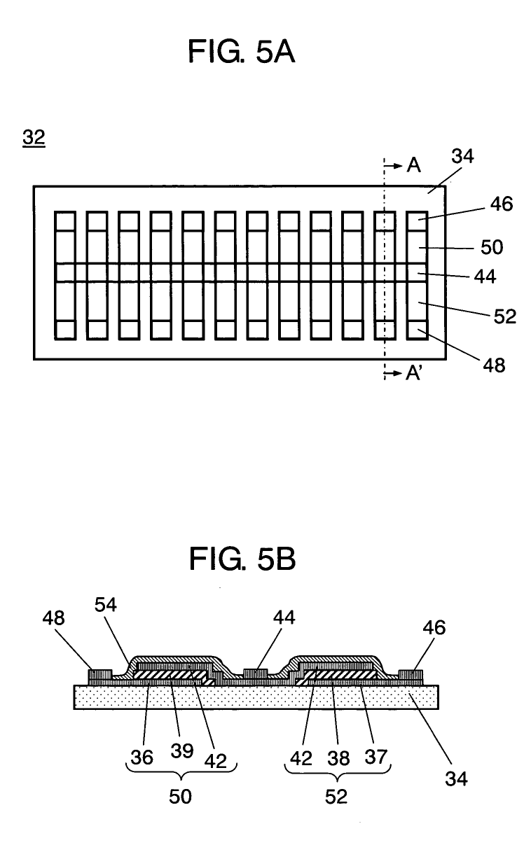

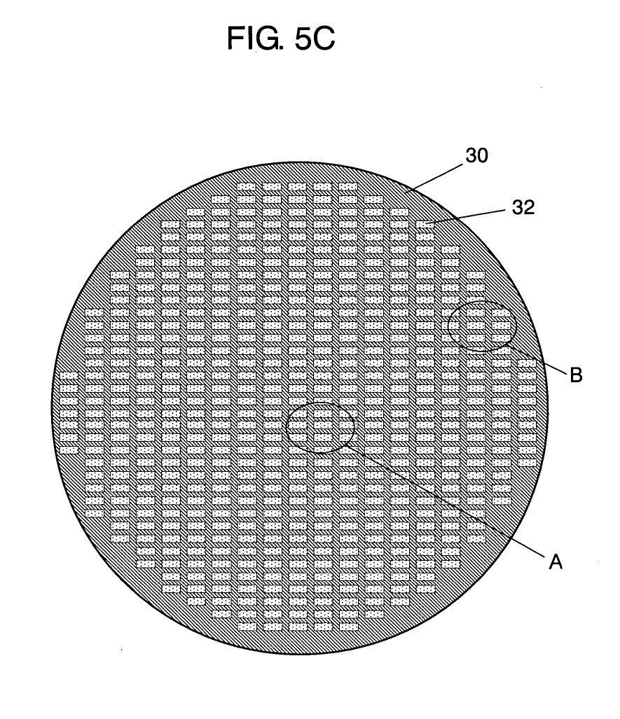

Explanation will be given below on the manufacturing method of sheet-like electronic component prepared with a film deposition apparatus on which is mounted said mask unit 21, with reference to FIG. 5.

FIG. 5A is a plan view of a sheet-like electronic component, while FIG. 5B is a sectional view A-A′ of FIG. 5A. And, FIG. 5C is a drawing explaining the relation of film position among a plurality of electronic components formed on a sheet-like substrate.

As shown in FIG. 5C, on a sheet-like substrate 30 are formed a plurality of electronic components 32 by using the mask unit 21. And, the electronic components 32 are separated in prescribed shape from the sheet-like substrate 30 by means of a dicing saw, etc. to be produced into electronic components 32 as indicated in FIG. 5A. For example, in the case of electronic components 32 of layered construction, a plurality of pattern forming masks is replaced at each time of film deposition, to form the component by using the mask unit 21.

In the following lines, explanation will be given by taking arrayed capacitor elements formed by using 4 pattern forming masks for example. The present invention provides great effects when making an electronic component 32 of layered film construction formed with at least 2 pattern forming masks.

In the first place, as shown in FIG. 5B, on a substrate 34 of polyimide, for example, is formed a lower electrode layer 36 made of aluminium, etc. by using the first pattern forming mask. And, except for part of the lower electrode layer 36, on its surface are formed dielectric films 38, 39 with silicon dioxide or barium titanate, etc. for example, by using the second pattern forming mask.

Next, on the dielectric films 38, 39 is formed an upper electrode layer 42 by using the third pattern forming mask. And, the connecting electrodes 46, 48 of the lower electrode layers 36, 37 and the connecting electrode 44 of the upper electrode layer 42 are formed with a layered film construction of copper, nickel, gold, etc. for example, by using the fourth pattern forming mask.

An electronic component 32 composed of arrayed capacitor elements 50, 52 is manufactured with the above-described process. Lastly, an electronic component 32 with excellent environmental resistance is realized by forming an insulated protective layer 54 except for the connecting electrodes 44, 46, 48.

In the case where an electronic component 32 is formed with a conventional mask unit 3, a displacement is produced between the mask pattern position and the previous film pattern position, at each time of formation of film, because of a difference in thermal expansion between the sheet-like substrate 30 and the pattern forming masks. And, that difference is more conspicuous at the portion B of the sheet-like substrate 30 indicated in FIG. 5C than at the portion A. Especially with the dielectric films 38, 39 taking a long film deposition time, dispersion of film thickness resulting from the film deposition time and displacement of patterns are produced. As a result, dispersion is produced in the facing areas of the upper electrode layer 42 and the lower electrode layers 36, 37 formed on it, and the characteristics of the electronic component 32 formed in the sheet-like substrate 30 are greatly affected by the deposited film position. In the case where the electronic component 32 is a capacitor element, it becomes a cause of dispersion of the capacity.

On the other hand, in the case where an electronic component 32 is manufactured by using the mask unit 21 according to the present invention, an electronic component 32 with sharply reduced dispersion of characteristics due to the deposited film position of the sheet-like substrate 30 can be realized, thanks to a small displacement with each film deposition pattern.

### Second Exemplary Embodiment

Explanation will be given hereinafter, on the mask unit according to the second exemplary embodiment of the present invention. Same symbols are used for elements identical to those explained in the first exemplary embodiment.

FIG. 6 is a sectional view showing the construction of a mask unit according to this exemplary embodiment. As shown in FIG. 6, the mask unit 26 according to this exemplary embodiment is different from that of the first exemplary embodiment in the construction of the shielding mask 27. Namely, the shielding mask 27 has a coated layer 27B realized by coating a material of low radiation rate such as aluminium (Al), etc. on the under surface of a metal sheet 27A such as stainless steel (SUS), etc. by vapor deposition method, etc. In other points, the shielding mask 27 is the same as the shielding mask 22 explained in the first exemplary embodiment. The coated layer 27B restricts the radiation on the mask 11 from the shielding mask 27 which is heated with the radiant heat from the vapor deposition source during the film deposition process. As a result, the temperature rise in the mask 11 is controlled, sharply reducing deformation due to heat of the mask 11.

By forming a coated layer 27B on the under surface of the shielding mask 27 and coating aluminium (Al), etc. also on the top face of the mask 11, it becomes possible to reflect the radiant heat from the shielding mask 27 on the mask 11, further reducing the temperature rise in the mask 11.

Moreover, one may also form the frame 25 with a material such as copper (Cu), carbon (C), etc. for example, having a larger thermal conductivity than the material of the shielding mask 27, and put it in close contact with the substrate holder 9. As method for putting them in close contact with each other, the method of putting a graphite sheet, for example, between the frame 25 and the substrate holder 9 and fastening them by screwing is desirable, because it is simple and easy and can transfer heat efficiently. Furthermore, it may also be all right to put a graphite sheet between the shielding mask 22 and the frame 25 or between the substrate holder 9 and the table 8.

This makes it possible to transfer heat efficiently through the frame 25 to the substrate holder 9, even if the shielding mask 27 is heated with radiant heat from the source of vapor deposition or heat by collision of ions at the time of plasma discharge. Still more, the outer circumferential area of the shielding mask 27 is not heated easily, because it is covered with the frame 25. As a result of those facts, the temperature rise in the shielding mask 27 itself is restricted. Yet more, in this exemplary embodiment, a coated layer 27B made of a material such as aluminium (Al), etc. is formed on the plane facing the mask 11, enabling to control radiant heat and prevent heat transfer from the shielding mask 27 to the mask 11. Therefore, the temperature rise of the mask 11 and the substrate 10 can be further restricted, and this enables to form a film of excellent reproducibility, without producing any displacement of patterns even when fine patterns are formed thick.

On a film deposition apparatus similar to that indicated in FIG. 3 on which is installed a mask unit 26 constructed as above was formed a pattern having a film thickness of approximately 3 μm on the substrate 10. As a result, the displacement of pattern resulting from thermal expansion of the mask 11 was reduced to no more than 25 μ, at the pattern opening 12 disposed near the outer circumference of a 100 mm square substrate 10.

Yet more, it became clear that, even in the case where the film deposition time is extended to form a film with a total thickness of 5 μm or so, there is hardly any change in the displacement of pattern of the mask 11, with the use of the mask unit 26.

And, it has been found that the mask unit 26 of this exemplary embodiment is effective also when forming fine patterns of a thick film.

What is claimed is:

1. A mask unit comprising:
a pattern forming mask disposed closely above a film, which is formed on a surface of a substrate held on a substrate holder, and having a prescribed pattern opening; and
a shielding mask disposed above the pattern forming mask and having a pattern opening larger than the pattern opening of the pattern forming mask,
wherein the pattern forming mask and the shielding mask are held with a prescribed clearance therebetween above the substrate.

2. The mask unit according to claim 1,
wherein a spacer formed with a material whose thermal conductivity is smaller than that of the shielding mask is placed in the prescribed clearance between the pattern forming mask and the shielding mask.

3. The mask unit according to claim 2,
wherein at least central parts of the pattern forming mask and the shielding mask are bonded together via the spacer.

4. The mask unit according to claim 1,
wherein at least a surface, which is confronted with the pattern forming mask, of the shielding mask is coated with a material of a radiation rate lower than that of the shielding mask.

5. The mask unit according to claim 1,
wherein an outer periphery of a surface, which is opposite to the pattern forming mask, of the shielding mask is covered with a frame made of a metal having a thermal conductivity not smaller than that of the shielding mask,
wherein a heat conductive member passing by sides of the pattern forming mask and the substrate is provided integrally with the frame, from around the frame to the substrate holder.

6. The mask unit according to claim 1,
wherein when an interval between the plurality of pattern openings at the pattern forming mask is larger than a prescribed dimension, the pattern opening at the shielding mask is formed so as to be larger than the pattern opening at the pattern forming mask by the prescribed dimension,
wherein when the interval between the plurality of pattern openings at the pattern forming mask is not larger than the prescribed dimension, the pattern opening at the shielding mask is formed so as to be larger than an area where the plurality of pattern openings at the pattern forming mask are combined by the prescribed dimension.

7. A film deposition apparatus comprising:
(a) a mask unit including:
(a-1) a pattern forming mask disposed closely above a film, which is formed on a surface of a substrate held on a substrate holder, and having a prescribed pattern opening;
(a-2) a shielding mask disposed above the pattern forming mask and having a pattern opening larger than the pattern opening of the pattern forming mask;
(b) a table cooled at a prescribed temperature and placed so as to be contacted with a lower surface of the substrate holder of the mask unit; and
(c) a vapor deposition source, which is placed at a vacuum chamber, for forming a prescribed film on a surface of the substrate disposed on the mask unit,
wherein the pattern forming mask and the shielding mask are held with a prescribed clearance therebetween above the substrate.

8. A method of manufacturing a sheet-like electronic component having at least 2 laminated films comprising:
(a) forming a first pattern on a surface of a sheet-like substrate by using a mask unit, the mask unit including:
a first pattern forming mask disposed closely above a film, which is formed on a surface of the sheet-like substrate held on a substrate holder, and having a prescribed pattern opening; and
a shielding mask disposed above the first pattern forming mask and having a pattern opening larger than the pattern opening of the first pattern forming mask, the first pattern forming mask and the shielding mask being held with a prescribed clearance therebetween above the substrate; and
(b) forming a second pattern on the first pattern by installing a second pattern forming mask, which differs from the first pattern forming mask, at the mask unit.
